(19) United States
(12) Patent Application Publication
(10) Pub. No.: US 2026/0239953 A1
(43) Pub. Date: Aug. 13, 2026

(54) SEMICONDUCTOR INTEGRATED CIRCUIT AND EQUIPMENT

(71) Applicant: CANON KABUSHIKI KAISHA, Tokyo (JP)

(72) Inventors: KOJI AOKI, Kanagawa (JP); KOICHI IWAO, Tokyo (JP); MASATO SASAKI, Tokyo (JP)

(21) Appl. No.: 19/530,523

(22) Filed: Feb. 5, 2026

(30) Foreign Application Priority Data
Feb. 12, 2025 (JP) 2025-020990

(51) Int. Cl. H10W 20/41; H10W 20/40; H10W 20/42

(52) U.S. Cl. CPC H10W 20/427; H10W 20/42; H10W 20/435; H10W 20/496

(57) ABSTRACT

A semiconductor integrated circuit comprises a plurality of circuit regions, each of which includes a semiconductor region including a transistor, and in which a semiconductor layer is formed by divisional exposure; and a wiring layer arranged to correspond to the semiconductor layer. Each of the plurality of circuit regions includes a first semiconductor region and a second semiconductor region. Capacitor cells are arranged in the first semiconductor region and the second semiconductor region. The wiring layer includes a connecting portion for connecting a power supply wiring and the capacitor cell. The number of the connecting portions is different between a first portion of the wiring layer arranged to correspond to the first semiconductor region and a second portion of the wiring layer arranged to correspond to the second semiconductor region.

### BACKGROUND

### Field of the Technology

The present disclosure relates to a semiconductor integrated circuit and equipment.

### Description of the Related Art

A logic cell in a semiconductor integrated circuit is supplied with a power supply voltage via a power supply wiring. If the power supply wiring is long, or if the power supply wiring cannot be routed to an appropriate location, a voltage drop (to be referred to as an "IR drop") can occur due to the resistance of the power supply wiring and a current flowing through the power supply wiring.

Japanese Patent Laid-Open No. 2005-332979 discloses that a decoupling capacitor is arranged in a semiconductor integrated circuit to reduce a voltage drop.

When manufacturing a semiconductor integrated circuit, a method may be used in which a plurality of identical circuit patterns are formed on a substrate by exposure. This exposure method is called divisional exposure. By manufacturing a semiconductor integrated circuit by divisional exposure, identical circuit patterns can be formed in a plurality of different exposure regions.

### SUMMARY

One disclosed embodiment provides a technique advantageous in appropriate power supply to a plurality of circuits having identical circuit patterns.

According to one aspect of the disclosure, there is provided a semiconductor integrated circuit comprising: a plurality of circuit regions, each of which includes a semiconductor region including a transistor, and in which a semiconductor layer is formed by divisional exposure; and a wiring layer arranged to correspond to the semiconductor layer, wherein each of the plurality of circuit regions includes a first semiconductor region and a second semiconductor region, capacitor cells are arranged in the first semiconductor region and the second semiconductor region, the wiring layer includes a connecting portion for connecting a power supply wiring and the capacitor cell, and the number of the connecting portions is different between a first portion of the wiring layer arranged to correspond to the first semiconductor region and a second portion of the wiring layer arranged to correspond to the second semiconductor region.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view for explaining a semiconductor integrated circuit;

FIG. 2 is a view for explaining connecting portions in a wiring layer;

FIG. 3 is a view for explaining connections between capacitor cells and wirings; and

FIG. 4 is a view for explaining an application of the semiconductor integrated circuit to equipment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In a semiconductor integrated circuit, a circuit is formed in a semiconductor region including a transistor. The circuit can include functions of an arithmetic circuit, a control circuit, an input/output circuit, and the like. In this embodiment, in a semiconductor integrated circuit, identical circuit patterns are formed in the first circuit region and the second circuit region different from the first circuit region in a semiconductor layer by divisional exposure. However, the semiconductor integrated circuit is not limited to a circuit including functions of an arithmetic circuit, a control circuit, and an input/output circuit. The semiconductor integrated circuit may be a circuit that includes some of these functions or a function different from these, for example, a signal processing circuit or a photoelectric conversion element. The number of circuit regions manufactured by divisional exposure is not limited to two (i.e., the first circuit region and the second circuit region).

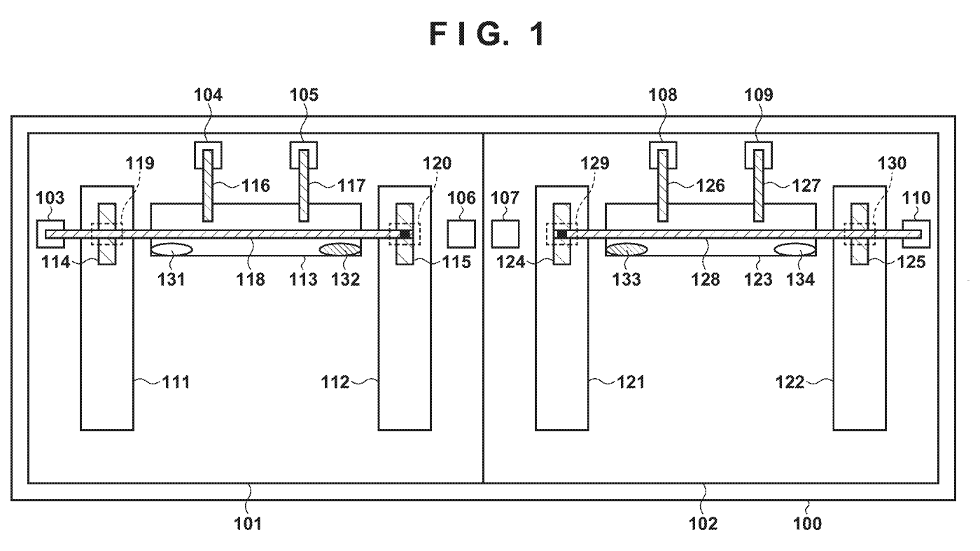

A semiconductor integrated circuit according to an embodiment will be described with reference to FIG. 1. FIG. 1 is a plan view of a semiconductor integrated circuit. A semiconductor integrated circuit 100 includes a first circuit region 101 and a second circuit region 102. In the example shown in FIG. 1, two circuit regions are shown. However, the number of circuit regions is not limited to two, and may be larger than two. Identical circuit patterns are formed in the first circuit region 101 and the second circuit region 102 by divisional exposure.

In the first circuit region 101, a first circuit pattern 111, a second circuit pattern 112, and a third circuit pattern 113 can be arranged. In the first circuit pattern 111, a first capacitor cell region 114 is arranged, where a logic cell or a capacitor cell can be arranged. In the second circuit pattern 112, a second capacitor cell region 115 is arranged, where a logic cell or a capacitor cell can be arranged similarly. A plurality of capacitor cells can be arranged in the first capacitor cell region 114 and the second capacitor cell region 115. The capacitor cells may be arranged in the same pattern in the first capacitor cell region 114 and the second capacitor cell region 115. A wiring layer is arranged to correspond to the circuit pattern in the first circuit region 101. Power supply pads 103 to 106 used for power supply are arranged in the wiring layer. Other circuits and power supply pads are also arranged, but illustration thereof is omitted for descriptive convenience.

The power supply pad 104 is connected to a first power supply wiring 116, and the power supply pad 105 is connected to a second power supply wiring 117. Furthermore, the power supply pad 103 is connected to a third power supply wiring 118 to supply a power supply voltage to the second circuit pattern 112. At a connecting portion with the capacitor cells arranged in the first capacitor cell region 114 in the first circuit pattern 111, the third power supply wiring 118 is not connected to the capacitor cells, or even if it is connected, the third power supply wiring 118 is connected to the capacitor cells at fewer connecting portions than in the second capacitor cell region 115, as will be described later. Furthermore, the third power supply wiring 118 is connected to the capacitor cells at a connecting portion with the capacitor cell arranged in the second capacitor cell region 115 in the second circuit pattern 112. The third power supply wiring 118 is connected to the capacitor cells arranged in the second capacitor cell region 115 at more connecting portions than in the first capacitor cell region 114. A power supply voltage is supplied using the power supply pad 103. The power supply pad 106 may not be used in the first circuit region 101.

In the second circuit region 102, a fourth circuit pattern 121, a fifth circuit pattern 122, and a sixth circuit pattern 123 are arranged. In the fourth circuit pattern 121, a fourth capacitor cell region 124 arranged, where a logic cell or a capacitor cell can be arranged. In the fifth circuit pattern 122, a fifth capacitor cell region 125 is arranged, where a logic cell or a capacitor cell can be arranged. A plurality of capacitor cells can be arranged in the first capacitor cell region 114 and the second capacitor cell region 115. Power supply pads 107 to 110 are also arranged. Other circuits and power supply pads are also arranged, but illustration thereof is omitted for descriptive convenience. The capacitor cells can be formed in the same arrangement in the first circuit region 101 and the second circuit region 102.

The power supply pad 108 is connected to a fourth power supply wiring 126, and the power supply pad 109 is connected to a fifth power supply wiring 127. Furthermore, the power supply pad 110 is connected to a sixth power supply wiring 128 to supply a power supply voltage to the fourth circuit pattern 121. At a connecting portion with the fourth capacitor cell region 124 in the fourth circuit pattern 121, the sixth power supply wiring 128 is connected to a capacitor cell. Furthermore, at a connecting portion with the fifth capacitor cell region 125 in the fifth circuit pattern 122, the sixth power supply wiring 128 is not connected to the capacitor cell, or even if it is connected, the sixth power supply wiring 128 is connected to the capacitor cells at fewer connecting portions than in the fourth capacitor cell region. A power supply voltage is supplied using the power supply pad 110. The power supply pad 107 may not be used in the second circuit region 102.

Next, a voltage drop (to be referred to as an "IR drop") in the semiconductor integrated circuit 100 formed by divisional exposure will be described, which occurs due to the resistance of the power supply wiring in each of the first circuit region 101 and the second circuit region 102 having identical circuit patterns, and a current flowing through the power supply wiring. First, a portion of the third circuit pattern 113 in the first circuit region 101 shown in FIG. 1 will be described. The third circuit pattern 113 is supplied with the power supply voltage from the power supply pads 104 and 105 via the power supply wirings 116 and 117. In a case where the power supply capability of the power supply wirings 116 and 117 is insufficient, the power supply voltage is supplied from the power supply pad 103 via the third power supply wiring 118.

However, a portion of the third circuit pattern 113 shown as a region 132 is farther from the power supply pad 103 than a region 131. In a case where the power supply voltage is supplied via the third power supply wiring 118, the wiring from the power supply pad 103 is long and the influence of the IR drop is large. On the other hand, a portion of the third circuit pattern 113 shown as the region 131 is close to the power supply pad 103, so that the power supply wiring is short and the influence of the IR drop is small.

Therefore, by connecting the capacitor cell arranged in the second capacitor cell region 115 in the second circuit pattern 112 to the power supply via the third power supply wiring 118 arranged in the wiring layer, the influence of the IR drop in the region 132 can be reduced. On the other hand, in the region 131 of the third circuit pattern 113 in the first circuit region 101, the wiring length from the power supply pad 103 is shorter than in the region 132, so that the influence of the IR drop is smaller than in the region 132. Hence, the capacitor cell in the first capacitor cell region 114 arranged in the first circuit pattern 111 need not be connected to the third power supply wiring 118.

Similarly, the sixth circuit pattern 123 in the second circuit region 102 will be described. The sixth circuit pattern 123 is supplied with the power supply voltage from the power supply pads 108 and 109 via the power supply wirings 126 and 127. In a case where the power supply capability of the power supply wirings 126 and 127 is insufficient, the power supply voltage is supplied from the power supply pad 110 via the sixth power supply wiring 128.

A portion of the sixth circuit pattern 123 shown as a region 133 is farther from the power supply pad 110 than a region 134, so that the power supply wiring is long and the influence of the IR drop is large. On the other hand, a portion of the sixth circuit pattern 123 shown as the region 134 is close to the power supply pad 110, so that the power supply wiring is short and the influence of the IR drop is small.

Therefore, by connecting the capacitor cell arranged in the fourth capacitor cell region 124 in the fourth circuit pattern 121 to the sixth power supply wiring 128 arranged in the wiring layer, the influence of the IR drop in the region 133 is reduced. On the other hand, in the portion shown as the region 134 of the sixth circuit pattern 123 in the second circuit region 102, the influence of the IR drop is smaller than in the portion shown as the region 133. Hence, the capacitor cell in the fifth capacitor cell region 125 arranged in the fifth circuit pattern 122 is not connected to the sixth power supply wiring 128.

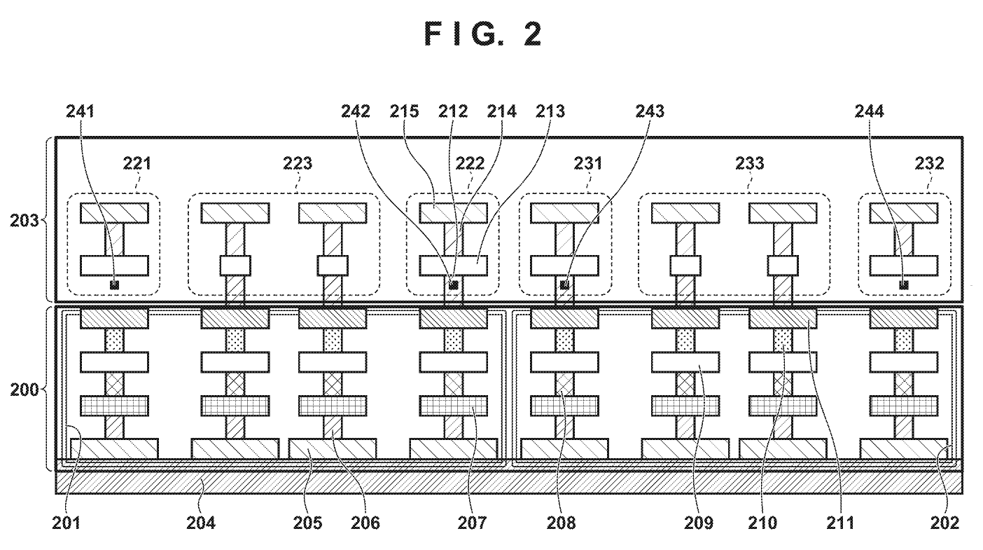

As described above, the number of connecting portions between the capacitor cells and the power supply wiring is changed between the first circuit pattern 111 and the second circuit pattern 112 arranged in the first circuit region. In the portion of the first circuit pattern 111, the power supply wiring is not connected to the capacitor cell, or fewer connecting portions are arranged in comparison to the portion of the second circuit pattern 112. With this, the IR drop can be suppressed. In addition, since the number of capacitor cells can be decreased, a leakage current caused by the capacitor cell can be suppressed. Wiring layers are connected by a via (VIA). The connection and non-connection between the power supply wiring and capacitor cells are realized by providing a VIA connecting portion for connecting the wiring and a VIA non-connecting portion for non-connecting the wiring in regions 119 and 120, respectively, where connecting portions are arranged. The VIA connecting portion and the VIA non-connecting portion will be described with reference to FIG. 2. Note that the IR drop and leakage current can be suppressed in the second circuit region in a similar manner.

FIG. 2 is a view showing the first circuit region and the second circuit region formed by divisional exposure, and connections between wiring layers in each circuit region. FIG. 2 shows a section of the wiring structure of the semiconductor integrated circuit shown in FIG. 1. A first circuit region 201 and a second circuit region 202, each indicated by a rectangular frame in FIG. 2, include identical circuit patterns formed by divisional exposure, and correspond to the first circuit region 101 and the second circuit region 102 in FIG. 1, respectively. Capacitor cells are formed in the first circuit region and the second circuit region according to the identical circuit patterns.

On a substrate 204, wirings are formed in multiple layers. In this example, a wiring layer formed by divisional exposure and close to the substrate 204 is referred to as a lower wiring layer 200. A wiring layer connected to the lower wiring layer 200 is referred to as an upper wiring layer 203. Wiring layers are numbered with increasing numbers sequentially starting from the wiring layer in the lower layer closest to the substrate 204: the first layer, the second layer, and the third layer. In this example, the lower wiring layer 200 includes three layers, but can include more or less wiring layers. The wiring layers are connected by forming a via (VIA) hole in the connecting portion and forming an electric connection through the via hole. In the following description, the via (VIA) will be regarded as a structure for electrically connecting the wiring layers. The VIA connecting the nth layer of the wiring layer to the layer ((n-1)th layer) lower than the nth layer will be referred to as the nth layer VIA.

A polysilicon layer 205 and a first wiring layer 207 are connected by a first layer VIA 206. The first wiring layer 207 and a second wiring layer 209 are connected by a second layer VIA 208. The second wiring layer 209 and a third wiring layer 211 are connected by a third layer VIA 210. Logic cells and capacitor cells are arranged in each circuit region. A signal wiring for connecting logic cells, a power supply wiring for connection to the power supply voltage, and the like are arranged in the wiring layer, and the signal wiring and the power supply wiring can be connected by a wiring arranged in the wiring layer.

Here, the first circuit region 201 and the second circuit region 202 include identical circuit patterns. When a signal connection between different circuit regions or a power supply connection is required, circuits are connected using a fourth wiring layer 213 or a fifth wiring layer 215 arranged in the upper wiring layer 203. The upper wiring layer 203 is formed using a mask including different patterns between the first circuit region 201 and the second circuit region 202. In this example, a fourth layer VIA 212 and a fifth layer VIA 214 can be used for connection to the fourth wiring layer 213 and the fifth wiring layer 215 in the upper wiring layer 203. Note that in this example, the upper wiring layer 203 includes two wiring layers, but the number of wiring layers is not limited to two.

The third wiring layer 211, which is the uppermost wiring layer in the lower wiring layer 200, and the fourth wiring layer 213 arranged in the upper wiring layer 203 are connected by the fourth layer VIA 212. The fourth wiring layer 213 and the fifth wiring layer 215 are connected by the fifth layer VIA 214. Note that the wiring layers and the VIAs used for connection shown in FIG. 2 represent an example of a wiring used for a power supply wiring, and a description of other wirings and circuits arranged in each circuit region will be omitted.

A first portion 221 indicated by a dotted line in the upper wiring layer 203 in FIG. 2 represents a portion of the upper wiring layer 203 corresponding to the first circuit pattern 111. Similarly, a second portion 222 indicated by a dotted line represents a portion of the upper wiring layer 203 corresponding to the second circuit pattern 112. A third portion 223 indicated by a dotted line represents a portion of the upper wiring layer 203 corresponding to the third circuit pattern 113.

Similarly, a fourth portion 231 represents a portion of the upper wiring layer 203 corresponding to the fourth circuit pattern 121. A fifth portion 232 represents a portion of the upper wiring layer 203 corresponding to the fifth circuit pattern 122. A sixth portion 233 represents a portion of the upper wiring layer 203 corresponding to the sixth circuit pattern 123.

A location denoted by reference numeral 241 in the first portion represents a non-connecting location to the wiring in the lower layer and is referred to as a VIA non-connecting portion 241. A location denoted by a reference numeral 242 in the second portion represents a connecting location to the wiring in the lower layer and is referred to as a VIA connecting portion 242. The upper wiring layer 203 corresponding to the second circuit region 102 includes a VIA connecting portion 243 and a VIA non-connecting portion 244. No via hole may be provided in the VIA non-connecting portion.

In this embodiment, a description will be provided assuming that the power supply wiring is arranged in the fifth wiring layer 215. The VIA connecting portion 242 connects, via the wiring in the lower wiring layer 200 and the fourth wiring layer 213, the capacitor cells arranged in the second capacitor cell region 115 to the power supply wiring connected to the fifth wiring layer 215. The VIA connecting portion 243 connects, via the wiring in the lower wiring layer 200 and the fourth wiring layer, the capacitor cells arranged in the fourth capacitor cell region 124 and the power supply wiring connected to the fifth wiring layer.

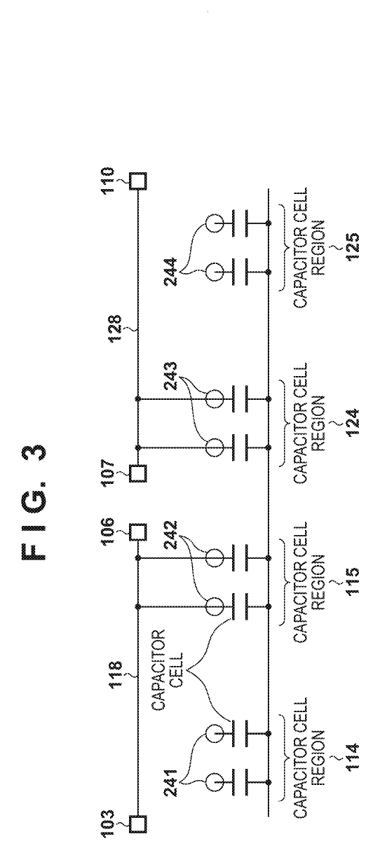

Here, the relationship of electrical connection among the capacitor cell, the wiring layer, and the power supply wiring will be described with reference to FIG. 3. Reference numerals in FIG. 3 correspond to reference numerals in FIGS. 1 and 2. FIG. 3 shows connections between the capacitor cells arranged in the circuit regions and the power supply wirings 118 and 128 in the upper wiring layer 203. In FIG. 3, two capacitor cells are arranged in each of the capacitor cell regions 114, 115, 124, and 125, but the number of capacitor cells is not limited thereto. One capacitor cell with high capacity may be arranged, or multiple capacitor cells with low capacity may be arranged.

The power supply pads 103, 106, 107, and 110 are connected to the power supply wirings 118 and 128. The capacitor cells in the first capacitor cell region 114 and the fifth capacitor cell region 125 are not connected to the power supply wiring. The capacitor cells arranged in the second capacitor cell region 115 and the fourth capacitor cell region 124 are connected to the power supply pads via the power supply wirings. In this embodiment, power is supplied to the power supply pad 103 and the power supply pad 110. Power is not supplied to the power supply pad 106 and the power supply pad 107. The capacitor cells arranged in the second capacitor cell region 115 and the fourth capacitor cell region 124 are connected to the power supply pads 103 and 110.

Referring back to FIG. 2, the connecting portions will be described. The region 132, where the IR drop is large in the first circuit region 101, is connected to the third power supply wiring 118 in the fifth wiring layer 215 from the capacitor cells arranged in the second capacitor region 115 and the lower wiring layer 200 in the second circuit pattern 112 via the VIA connecting portion 242. Similarly, the region 133, where the IR drop is large in the second circuit region 102, is connected to the sixth power supply wiring 128 in the fifth layer from the capacitor cell arranged in the fourth capacitor region 124 in the circuit pattern 121 and the lower wiring layer 200 via the VIA connecting portion 243. Thus, the IR drop can be suppressed in each of the regions 132 and 133.

On the other hand, in this embodiment, for the capacitor cells arranged in the first capacitor cell region 114, the VIA connecting portion is not arranged, as represented by the VIA non-connecting portion 241. Accordingly, the capacitor cell in the first capacitor cell region 114 is not connected to the third power supply wiring 118. Similarly, by providing the VIA non-connecting portion 244 at the position of the fourth layer VIA shown in FIG. 2, the capacitor cell arranged in the fifth capacitor cell region 125 is not connected to the sixth power supply wiring 128 without arranging the fourth layer VIA. In this embodiment, the capacitor cells in the first capacitor cell region 114 and the fifth capacitor cell region 125 are not connected to the power supply wirings. However, the IR drop and the leakage current can also be suppressed by making the number of capacitor cells connected to the power supply wirings in the first capacitor cell region 114 and the fifth capacitor cell region 125 smaller than that in the second capacitor cell region 115 and the fourth capacitor cell region 124.

As described above, in the region 132 where the IR drop is large in the third circuit pattern 113, the IR drop can be suppressed by connecting the capacitor cell in the second capacitor cell region 115 to the power supply wiring. Similarly, in the region 133 where the IR drop is large in the second circuit region 102, the IR drop can be suppressed by connecting the capacitor cell in the fourth capacitor cell region 124 to the power supply wiring.

As described in this embodiment, in a location where the IR drop needs to be suppressed, the capacitor cell is connected to the power supply via a VIA connection between the lower wiring layer 200 and the upper wiring layer 203. The number of connecting portions between the capacitor cells and the power supply wiring can be controlled in accordance with the number of VIA connections. By controlling the number of connecting portions, the variation between the IR drop in the region 131 and the IR drop in the region 132 can be suppressed. Similarly, the variation between the IR drop in the region 133 and the IR drop in the region 134 can be decreased.

Furthermore, it is also possible to suppress the variation in IR drop between the region 131 in the first circuit region and the region 133 in the second circuit region, which are identical circuit locations in the identical circuit patterns, and between the IR drops in the region 132 in the first circuit region and the region 134 in the second circuit region, which are identical circuit locations in the identical circuit patterns.

A plurality of capacitor cells may be arranged in the capacitor cell region, and the number of capacitor cells connected to the power supply wiring may be changed. Increasing the number of connections between one capacitor cell and the power supply wiring may also be advantageous in suppressing the IR drop. In that case, the capacitor cell may have a large capacitance value.

Note that in the above description, a case has been described where connections to the capacitor cells arranged in the first circuit region 201 and the second circuit region 202 corresponding to divisional exposure are made from the fourth wiring layer 213 via the fourth layer VIA 212. However, connecting portions and non-connecting portions between the capacitor cells and the power supply wiring may be provided in other wiring layers. For example, the VIA connecting portions and the VIA non-connecting portions may be provided in the fifth wiring layer 215 which is the higher wiring layer. When connecting the power supply wiring, connections to the capacitor cells arranged in the first circuit region 201 and the second circuit region 202 may be made via the fifth layer VIA 214, the fourth wiring layer 213, and the fourth layer VIA 212. Although not shown, connections to the capacitor cells may be made via a wiring layer higher than the fifth wiring layer 215.

As described above, by VIA-connecting the power supply wiring to the capacitor cells arranged in a broader region via the other wiring layer, it is possible to connect the required capacitor cell to the required location. The third wiring layer has been described as the uppermost wiring layer formed by divisional exposure, but the fourth wiring layer, the fifth wiring layer, or the like may be formed as the uppermost wiring layer.

The number of connecting portions is changed between the first capacitor cell region 114 and the second capacitor cell region 115, but the number of connecting portions may also be changed between the first capacitor cell region 114 and the fourth capacitor cell region 124. When the IR drop is large in the fourth capacitor cell region 124, it can be configured to increase the number of connecting portions between the power supply wiring and the capacitor cells in comparison with the first capacitor cell region 114. The number of connecting portions between the power supply wiring and the capacitor cells in the second capacitor cell region 115 may be increased in comparison to the number of connecting portions in the fifth capacitor cell region 125.

As for the number of capacitor cells connected to the power supply wiring, the capacitor cells arranged in the capacitor cell region may be VIA-connected to the power supply wiring in accordance with the required capacitance value. Alternatively, only some capacitor cells in the capacitor cell region may be VIA-connected to the power supply wiring. Hence, it is sufficient that the capacitor cells arranged in the capacitor cell region cover the required capacitance value.

In this embodiment, a case has been described where the capacitor cells are provided in the first circuit pattern 111, the second circuit pattern 112, the fourth circuit pattern 121, and the fifth circuit pattern 122. However, similar capacitor cell regions may be provided in the third circuit pattern 113 and the sixth circuit pattern 123. Furthermore, the capacitor cell region may be provided at a location other than the circuit patterns shown in the drawings, and the connection between the power supply wiring and the capacitor cell may be controlled.

The capacitor cell arranged in the capacitor cell region may have different capacitances. For example, different capacitor cells may be arranged in combination of a standard capacitor cell, a double standard capacitor cell, and a quadruple standard capacitor cell. In this case, only the required capacitor cells may be connected in accordance with the required capacitance value. Furthermore, in the above description, connections between the capacitor cells and power supply wirings for a single power supply voltage have been described, but the capacitor cells may be connected to power supply wirings for multiple power supply voltages.

There is a case where the first power supply voltage and the second power supply voltage different from each other are supplied to a semiconductor integrated circuit. In this case, a power supply wiring connected to the first power supply voltage may be connected to the capacitor cell arranged in each exposure region, and a power supply wiring connected to the second power supply voltage may not be connected to the capacitor cell arranged in each exposure region. To the contrary, a power supply wiring connected to the second power supply voltage may be connected to the capacitor cell arranged in each exposure region, and a power supply wiring connected to the first power supply voltage may not be connected to the capacitor cell arranged in each exposure region.

Alternatively, a power supply wiring connected to the first power supply voltage may be connected to the capacitor cell arranged in each exposure region, and a power supply wiring connected to the second power supply voltage may be simultaneously connected to the capacitor cell arranged in each exposure region. The number of VIA connections is controlled to suppress occurrence of the IR drop and suppress a leakage current.

According to the present disclosure, in a case where circuits having the same function as shown in FIG. 1 are formed by performing exposure a plurality of times using a common mask, connections between the power supply wiring and the capacitor cells in the capacitor cell region can be controlled for each exposure region by the number of VIAs. Thus, it is possible to mitigate the variation in IR drop between the exposure regions and within the exposure region without reducing common points in the exposure regions.

### Application Example of Semiconductor Integrated Circuit to Equipment

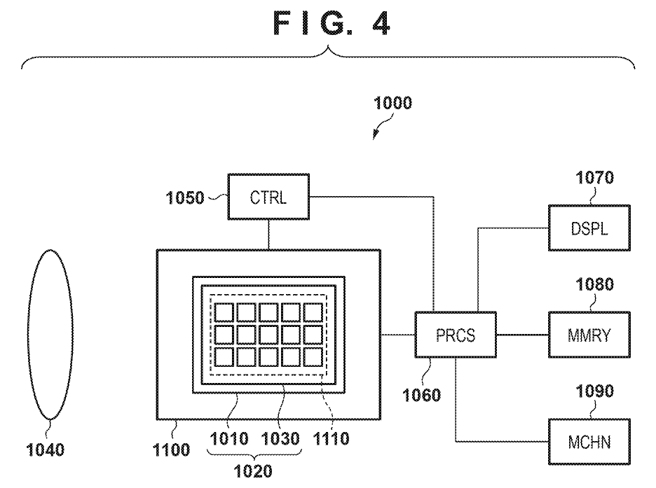

The following is a description of equipment 1000 that includes a semiconductor apparatus 1100 including a package 1020 on which a semiconductor chip 1110 including a semiconductor integrated circuit according to the above-described embodiment is mounted, as shown in FIG. 4. The semiconductor chip 1110 is accommodated in the package 1020 and mounted on the equipment 1000. In the arrangement shown in FIG. 4, the semiconductor chip 1110 includes the semiconductor integrated circuit according to the embodiment described above. The semiconductor apparatus 1100 can include the package 1020 including a base 1010 on which the semiconductor chip 1110 is fixed and a light transmissive member 1030 such as glass that faces the semiconductor chip 1110. The package 1020 can be provided with joining members such as wires and bumps that connect inner leads provided on the base 1010 to terminals such as pad electrodes provided on the semiconductor chip 1110.

The equipment 1000 can include at least one of an optical apparatus 1040, a control apparatus 1050, a processing apparatus 1060, a display apparatus 1070, a storage apparatus 1080, and a mechanical apparatus 1090. The optical apparatus 1040 is implemented by, for example, a lens, a shutter, and a mirror. The control apparatus 1050 controls the semiconductor chip 1110. The control apparatus 1050 is, for example, a semiconductor device such as an ASIC.

The processing apparatus 1060 processes a signal output from a semiconductor integrated circuit included in the semiconductor chip 1110. The processing apparatus 1060 is a semiconductor device such as a CPU or an ASIC for forming an Analog Front End (AFE) or a Digital Front End (DFE). For example, an image may be generated based on an image capturing signal at the time of detecting an event. The display apparatus 1070 is an EL display device or a liquid crystal display device that displays an information image obtained by the semiconductor chip 1110. The storage apparatus 1080 is a magnetic device or a semiconductor device that stores the information image obtained by the semiconductor chip 1110. The storage apparatus 1080 is a volatile memory such as an SRAM or a DRAM, or a nonvolatile memory such as a flash memory or a hard disk drive.

The mechanical apparatus 1090 includes a moving or propulsion unit such as a motor or an engine. In the equipment 1000, the signal output from the semiconductor chip 1110 is displayed on the display apparatus 1070 or transmitted to an external apparatus by a communication apparatus (not shown) included in the equipment 1000. Hence, the equipment 1000 may further include the storage apparatus 1080 and the processing apparatus 1060 in addition to the memory circuits and arithmetic circuits included in the semiconductor chip 1110. The mechanical apparatus 1090 may be controlled based on the signal output from the semiconductor chip 1110.

The equipment 1000 is suitable for electronic equipment such as an information terminal which has a shooting function, for example, a smartphone or a wearable terminal, or a camera, for example, an interchangeable lens camera, a compact camera, a video camera, or a monitoring camera. The mechanical apparatus 1090 in the camera can drive the components of the optical apparatus 1040 in order to perform zooming, an in-focus operation, and a shutter operation. Alternatively, the mechanical apparatus 1090 in the camera can move the optical apparatus 1040 in order to perform an anti-vibration operation.

Furthermore, the equipment 1000 can be transportation equipment such as a vehicle or a ship. The mechanical apparatus 1090 in the transportation equipment can be used as a moving apparatus. The equipment 1000 as the transportation equipment is suitable for equipment that transports the semiconductor chip 1110 or equipment that uses a shooting function to assist and/or automate drive steering. The processing apparatus 1060 for assisting and/or automating drive steering can perform, based on the information obtained by the semiconductor chip 1110, processing for operating the mechanical apparatus 1090 as a moving apparatus. Alternatively, the equipment 1000 may be medical equipment such as an endoscope, measurement equipment such as a distance measurement sensor, analysis equipment such as an electron microscope, office equipment such as a copy machine, or industrial equipment such as a robot.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-020990, filed February 12, 2025 which is hereby incorporated by reference herein in its entirety.

What is claimed is:

1. A semiconductor integrated circuit comprising:
a plurality of circuit regions, each of which includes a semiconductor region including a transistor, and in which a semiconductor layer is formed by divisional exposure; and
a wiring layer arranged to correspond to the semiconductor layer,
wherein
each of the plurality of circuit regions includes a first semiconductor region and a second semiconductor region,
capacitor cells are arranged in the first semiconductor region and the second semiconductor region,
the wiring layer includes a connecting portion for connecting a power supply wiring and the capacitor cell, and
the number of the connecting portions is different between a first portion of the wiring layer arranged to correspond to the first semiconductor region and a second portion of the wiring layer arranged to correspond to the second semiconductor region.

2. The circuit according to claim 1, wherein
the number of the connecting portions is different between the first portion of one circuit region of the plurality of circuit regions and the first portion of another circuit region.

3. The circuit according to claim 1, wherein
the capacitor cells include capacitor cells with different capacitance values.

4. The circuit according to claim 1, wherein
the capacitor cells are arranged in multiple locations in the first portion and the second portion.

5. The circuit according to claim 1, wherein
the capacitor cells are arranged in the same pattern in the first portion and the second portion.

6. The circuit according to claim 1, wherein
the connecting portion includes a via hole.

7. The circuit according to claim 6, wherein
the via hole is not arranged at a position where the power supply wiring and the capacitor cell are not connected.

8. The circuit according to claim 1, wherein
a first power supply pad connected to the power supply wiring is arranged in the first portion, and a second power supply pad connected to the power supply wiring is arranged in the second portion.

9. The circuit according to claim 8, wherein
power is supplied to at least one of the first power supply pad and the second power supply pad.

10. The circuit according to claim 1, further comprising another power supply wiring supplied with a voltage different from a voltage supplied to the power supply wiring,
wherein the other power supply wiring is not connected to the capacitor cell.

11. Equipment comprising:
a semiconductor integrated circuit defined in claim 1; and
a processing apparatus configured to process a signal output from the semiconductor integrated circuit.
